(19) United States
(12) Patent Application Publication
(10) Pub. No.: US 2015/0340484 A1
(43) Pub. Date: Nov. 26, 2015

(54) POWER DEVICE

(71) Applicants: EPISTAR CORPORATION, Hsinchu (TW); HUGA OPTOTECH INC, Taichung City (TW)

(72) Inventors: Ya-Yu YANG, Taichung City (TW); Heng-Kuang LIN, Taichung City (TW)

(21) Appl. No.: 14/715,750

(22) Filed: May 19, 2015

(30) Foreign Application Priority Data
May 20, 2014 (TW) 103117722

(51) Int. Cl. H01L 29/778; H01L 29/267; H01L 29/423; H01L 29/06

(52) U.S. Cl. CPC H01L 29/7787; H01L 29/0676; H01L 29/267; H01L 29/42304

(57) ABSTRACT

This disclosure discloses a power device. The power device comprises a substrate; a first semiconductor layer having a first band gap and disposed on the substrate; a second semiconductor layer having a second band gap being lager than the first band gap and disposed on the first semiconductor layer; a third semiconductor layer having a third band gap smaller than the second band gap layer and disposed on the second semiconductor layer; a source electrode disposed on the third semiconductor layer; a base electrode electrically connecting the source electrode; and a p-type metal-oxide layer disposed between the base electrode and the third semiconductor layer.

### REFERENCE TO RELATED APPLICATION

This application claims the right of priority based on TW application Serial No. 103117722, filed on May 20, 2014. The entire content of the application is hereby incorporated by reference in its entirety.

### BACKGROUND

1. Technical Field

The present disclosure relates to a power device, and in particular a power device with a base electrode disposed on a p-type metal-oxide layer.

2. Description of the Related Art

Recently, the use of gallium nitride (GaN) materials in optoelectronic devices and electronic devices develops rapidly. The power devices made of gallium nitride materials, such as AlGaN/GaN, have the characteristics of high electron mobility, can be operated in high temperature and severe conditions, and can provide high power. For the high power device, it is important to avoid the high electric field concentration at the edge of the gate channel so the electrical characteristics of the device are improved and the current collapse is prevented.

### SUMMARY OF THE DISCLOSURE

The present disclosure provides a light-emitting device with a light-emitting diode disposed on a substrate wherein the substrate is thermal conductive and transparent.

This disclosure discloses a power device. The power device comprises a substrate; a first semiconductor layer having a first band gap and disposed on the substrate; a second semiconductor layer having a second band gap being lager than the first band gap and disposed on the first semiconductor layer; a third semiconductor layer having a third band gap being smaller than the second band gap and disposed on the second semiconductor layer; a source electrode disposed on the third semiconductor layer; a base electrode electrically connecting the source electrode; and a p-type metal-oxide layer disposed between the base electrode and the third semiconductor layer.

### BRIEF DESCRIPTION OF THE DRAWING

The accompanying drawings are included to provide easy understanding of the application, and are incorporated herein and constitute a part of this specification. The drawings illustrate the embodiments of the application and, together with the description, serve to illustrate the principles of the application.

FIGS. 1A˜1F are views illustrating a method of making a power device in accordance with one embodiment of the present disclosure.

FIG. 2 illustrates a power device in the turn-on state in accordance with one embodiment of the present disclosure.

FIG. 3 illustrates a power device in accordance with another embodiment of the present disclosure.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure. In addition, these drawings are not necessarily drawn to scale. Likewise, the relative sizes of elements illustrated by the drawings may differ from the relative sizes depicted.

The following shows the description of embodiments of the present disclosure in accordance with the drawings.

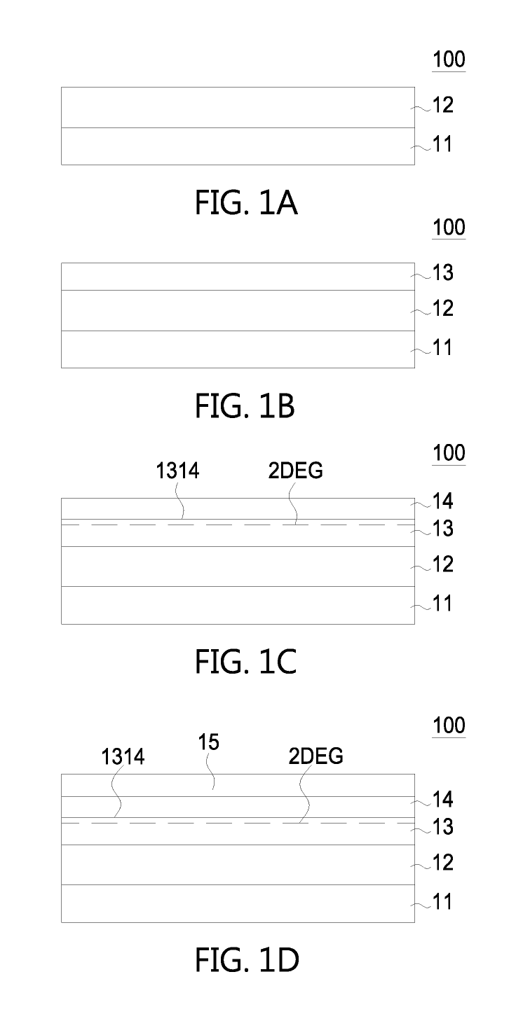

FIGS. 1A˜1F are views illustrating a method of making a power device in accordance with one embodiment of the present disclosure. Referring to FIGS. 1A˜1D, a buffer layer 12 is formed on the substrate 11, a first semiconductor layer 13 is formed on the buffer layer 12, a second semiconductor 14 is formed on the first semiconductor layer 13, and a third semiconductor layer 15 is formed on the second semiconductor layer 14. Referring to FIGS. 1E˜1F, a p-type metal-oxide layer 16 is formed on the third semiconductor layer 15, a base electrode 17 is formed on the p-type metal-oxide layer 16, a source electrode 18 and a drain electrode 19 are formed near the two sides of the p-type metal-oxide layer 16, and a gate electrode 20 is formed between the source electrode 18 and base electrode 17. In this present embodiment, the base electrode may influence a polarization effect of the power device to balance the positive electric charge and the negative electric charge to achieve the uniform electric field.

The substrate 11 comprises sapphire, SiC, GaN, or Si. The buffer layer 12 comprises group III-V materials, such as AlN or AlN/AlGaN. When Si substrate is used, the buffer layer is formed on the [111] plane of the Si substrate and grows along (0001) direction in order to reduce difference of lattice constant between the Si substrate and the epitaxial stack so the quality of the epitaxial stack is improved. It should be noted that a leakage path of the power device can be decreased by removing the whole or partial substrate to lower the leakage current.

The first semiconductor layer 13 has a first band gap, and the second semiconductor layer 14 has a second band gap larger than the first band gap of the first semiconductor layer 13, which means the lattice constant of the second semiconductor layer 14 is smaller than that of the first semiconductor layer 13. In the present embodiment, the first semiconductor layer 13 comprises InₓGa₍₁₋ₓ₎N wherein 0≦x<1 (ex. GaN), and the second semiconductor layer 14 comprises Al_{y}In_{z}Ga_{(1-z)}N wherein 0<y<1, 0≦z<1 (ex. AlGaN). The first semiconductor layer 13 and the second semiconductor layer 14 form the spontaneous polarization by themselves and the piezoelectric polarization by the different lattice constant therebetween to generate a two dimensional electron gas (2DEG) at a first interface 1314 between the first semiconductor layer 13 and the second semiconductor layer 14. It should be noted that the first semiconductor layer 13 and the second semiconductor layer 14 may be un-doped semiconductor layers. In other embodiments, the first semiconductor layer 13 and the second semiconductor layer 14 may be doped semiconductor layers and the dopant may be SiH4 (Silane) in order to increase the effect of the spontaneous polarization and the piezoelectric polarization and raise the 2DEG concentration at the first interface 1314.

The third semiconductor layer 15 has a third band gap smaller than the second band gap of the second semiconductor layer 14, which means lattice constant of the third semiconductor layer 15 is larger than that of the second semiconductor layer 14. In the present embodiment, the third semiconductor layer 13 comprises InₓGa₍₁₋ₓ₎N wherein 0≦x<1 (ex. GaN). Referring to FIG. 1E, the p-type metal-oxide layer 15 is formed on a top surface 151 of the third semiconductor layer 15. A predetermined area is defined by lithography process, and the p-type metal-oxide layer 16 is deposited on the predetermined area by RF magnetron sputter in low temperature process (500° C.), wherein the p-type metal-oxide layer 16 comprises NiO, MoO, CuO, ZnO, SnO₂, or other metal-oxide materials. The second semiconductor layer 14, the third semiconductor layer 15 and the p-type metal-oxide layer 16 form the reversed polarization by the different lattice constant between the second semiconductor layer 14 and the third semiconductor layer 15, and the p-type metal-oxide layer 16 formed on the third semiconductor layer 15 in order to raise the valence band (Ev) of the second semiconductor layer 14 over the Fermi level(Ef), and then a two dimensional hole gas (2DHG) can be generated at a second interface 1415 between the second semiconductor layer 14 and the third semiconductor layer 15 and below the p-type metal-oxide layer 16. It should be noted that the third semiconductor layer 15 may be un-doped semiconductor layers. In other embodiments, the third semiconductor layer 15 may be doped semiconductor layers and the doping substance may be SiH4 (Silane). Moreover, the third semiconductor layer 15 can be a protection layer to prevent the surface of the second semiconductor layer 14 from being damaged during the manufacturing process and avoid the concentration reduction of the two dimensional hole gas (2DHG). In the present embodiment, the p-type metal-oxide layer has high dopant concentration (>1E19) and better characteristics because the dopant concentration of the p-type metal-oxide layer is not influenced by the manufacturing process. The process to form the p-type metal-oxide layer is simpler because there is no need of wet/dry etch process to prevent surface of the device from being damaged seriously. The process to form the p-type metal-oxide layer in the lower temperature can reduce the decline of the device characteristics. The use of stripper in lithography process may be organic which is weak alkaline stripper (ex. acetone). Comparing with the strong acidic stripper used in wet/dry etch process (ex. hydrofluoric acid), the weak alkaline stripper can improve damage to the surface of the device.

Referring to FIG. 1F, p-type metal-oxide layer 16 is disposed between the base electrode 17 and the third semiconductor layer 15. The base electrode 17 may be made of a stack of Ni/Au or other metal materials and in ohmic contact with the p-type metal-oxide layer 16. The source electrode 18 and the drain electrode 19 are formed next to the base electrode 17 in different sides and on the third semiconductor layer 15. The source electrode 18 and the drain electrode 19 may be made of a stack of Ti/Al/Ti/Au, Ti/Al/Ni/Au or other metal materials and in ohmic contact with the third semiconductor layer 15, wherein the source electrode 18 is electrically connected to the base electrode 17. The gate electrode 20 is formed between the source electrode 18 and the p-type metal-oxide layer 16 and on the third semiconductor layer 15. The gate electrode 20 may be made of a stack of Ni/Au or other metal materials and in schottky contact with the third semiconductor layer 15. The source electrode 18, the drain electrode 19, and the gate electrode 20 can be electrically connected to an external circuit or a power supply (not shown). The source electrode 18, the drain electrode 19, and the gate electrode 20 can also control the operation state of the power device depending on the actual requirements and the distribution of the two dimensional electron gas (2DEG). It should be noted that the gate electrode 20 may be arranged far away from the drain electrode 19 and near the source electrode 18 to increase the breakdown voltage.

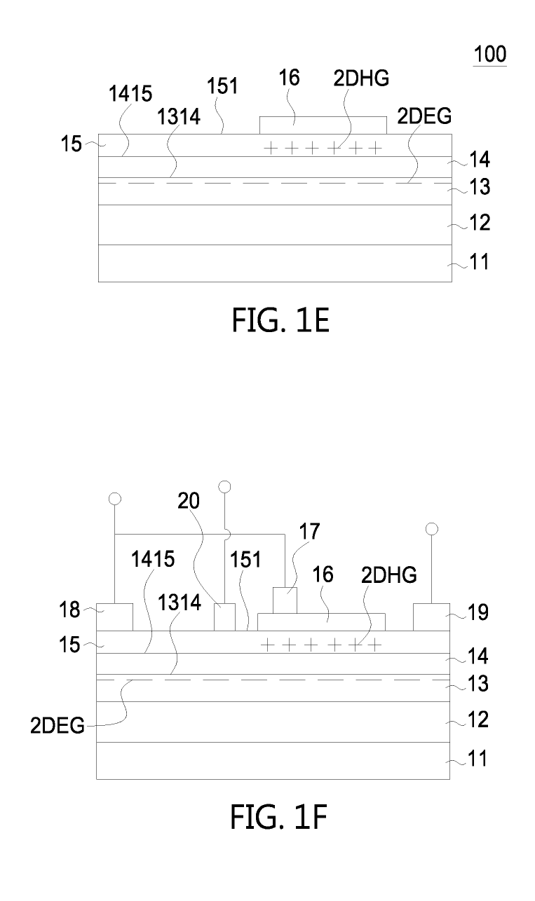

FIG. 2 illustrates a power device in the turn-on state in accordance with one embodiment of the present disclosure. The power device 100 is a normally on power device. When a forward voltage (ex. +600˜+1000V) is provided to the drain electrode 19, the base electrode 17 and the source electrode 18 are grounded (0V), and a reverse voltage (ex. −10˜−20V) is provided to the gate electrode 20, the conduction band (Ec) below the gate electrode 20 is raised over the Fermi level (Ef) to dissipate the two dimensional electron gas (2DEG), and then the power device is in the turn-off state (reverse biased state). In the meantime, the generation of two dimensional hole gas (2DHG) and the two dimensional electron gas (2DEG) below the p-type metal-oxide layer can alleviate the electric field concentrated too much below the gate electrode 20 and can distribute the electric field intensity to get the uniform electric field and prevent the current collapse and the device destruction. In the present embodiment, the potential of the base electrode 17 can be a constant by connecting the base electrode 17 to the ground (0V) in order to prevent the potential floating and to stabilize the device. It should be noted that the power device of the present embodiment may have high electron mobility because of its heterojunction structure formed between the GaN and AlGaN to achieve the switch speed and can be operated in the high frequency, high power and high temperature operation environment.

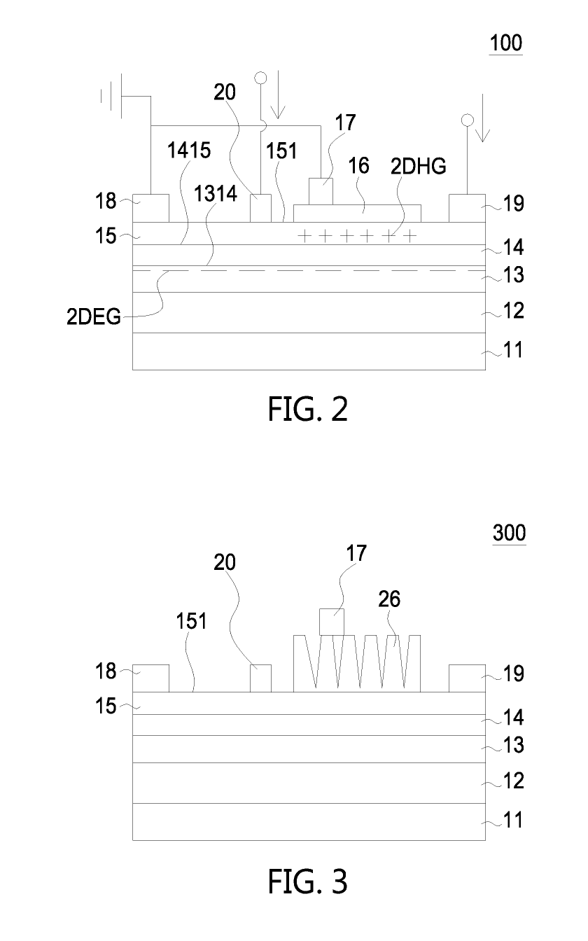

FIG. 3 illustrates a power device 300 in accordance with an embodiment of the present disclosure. The power device of this embodiment is similar to that of the above embodiment, expect that the p-type metal-oxide layer 26 is a nano-rod structure in order to increase the local concentration of two dimensional hole gas (2DHG), alleviate the electric field concentrated too much below the gate electrode, distribute the electric field intensity to get the uniform electric field and prevent the current collapse and the device destruction.

It is noted that the foregoing description has been directed to the specific embodiments of this invention. It will be apparent to those having ordinary skill in the art that other alternatives and modifications can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A power device comprising:
a substrate;
a first semiconductor layer having a first band gap and disposed on the substrate;
a second semiconductor layer having a second band gap lager than the first band gap and disposed on the first semiconductor layer;
a third semiconductor layer having a third band gap smaller than the second band gap and disposed on the second semiconductor layer;
a source electrode disposed on the third semiconductor layer;
a base electrode electrically connecting to the source electrode; and
a p-type metal-oxide layer disposed between the base electrode and the third semiconductor layer.

2. The power device of claim 1, further comprising a drain electrode wherein the p-type metal-oxide layer is disposed between the source electrode and the drain electrode.

3. The power device of claim 1, further comprising a gate electrode disposed between the source electrode and the base electrode.

4. The power device of claim 1, wherein the p-type metal-oxide layer comprises NiO [symbol] MoO [symbol] CuO [symbol] ZnO, or SnO₂.

5. The power device of claim 1, wherein the p-type metal-oxide layer comprises a nano-rods structure.

6. The power device of claim 1, further comprising a two dimensional electron gas and a first interface disposed between the first semiconductor layer and second semiconductor layer wherein the two dimensional electron gas generates at the first interface while the power device is in a turn-on state.

7. The power device of claim 1, further comprising a two dimensional hole gas and a second interface disposed between the second semiconductor layer and third semiconductor layer wherein the two dimensional hole gas forms at the second interface while the power device is in a turn-on state.

8. The power device of claim 1, wherein the first semiconductor layer comprises InₓGa₍₁₋ₓ₎N, wherein 0≦x<1.

9. The power device of claim 1, wherein the second semiconductor layer comprises Al_{y}In_{z}Ga_{(1-z)}N, wherein 0<y<1, 0≦z<1.

10. The power device of claim 1, wherein the third semiconductor layer comprises In_{w}Ga_{(1-w)}N, wherein 0≦w<1.

11. A power device, comprising:
a substrate;
a first semiconductor layer having a first lattice constant and disposed on the substrate;
a second semiconductor layer having a second lattice constant smaller than the first lattice constant and disposed on the first semiconductor layer;
a third semiconductor layer having a third lattice constant larger than the second lattice constant and disposed on the second semiconductor layer;
a source electrode disposed on the third semiconductor layer;
a base electrode electrically connecting to the source electrode; and
a p-type metal-oxide layer disposed between the base electrode and the third semiconductor layer.

12. The power device of claim 11, further comprising a drain electrode wherein the p-type metal-oxide layer is disposed between the source electrode and the drain electrode.

13. The power device of claim 11, further comprising a gate electrode disposed between the source electrode and the base electrode.

14. The power device of claim 11, wherein the p-type metal-oxide layer comprises NiO [symbol] MoO [symbol] CuO [symbol] ZnO, or SnO₂.

15. The power device of claim 11, wherein the p-type metal-oxide layer comprises a nano-rods structure.

16. The power device of claim 11, further comprising a two dimensional electron gas and a first interface disposed between the first semiconductor layer and second semiconductor layer wherein the two dimensional electron gas generates at the first interface while the power device is in a turn-on state.

17. The power device of claim 11, further comprising a two dimensional hole gas and a second interface disposed between the second semiconductor layer and third semiconductor layer wherein the two dimensional hole gas generates at the second interface while the power device is in a turn-on state.

18. The power device of claim 11, wherein the first semiconductor layer comprises InₓGa₍₁₋ₓ₎N and 0≦x<1.

19. The power device of claim 11, wherein the second semiconductor layer comprises Al_{y}In_{z}Ga_{(1-z)}N and 0<y<1, 0≦z<1.

20. The power device of claim 11, wherein the third semiconductor layer comprises In_{w}Ga_{(1-w)}N and 0≦w<1.
